(19) United States
(12) Patent Application Publication
(10) Pub. No.: US 2025/0270689 A1
(43) Pub. Date: Aug. 28, 2025

(54) FILM-FORMING METHOD AND FILM-FORMING APPARATUS

(71) Applicant: Tokyo Electron Limited, Tokyo (JP)

(72) Inventors: Minho CHOI, Yamanashi (JP); Yoshihiro TAKEZAWA, Yamanashi (JP); Tatsuya MIYAHARA, Yamanashi (JP)

(21) Appl. No.: 19/053,675

(22) Filed: Feb. 14, 2025

(30) Foreign Application Priority Data
Feb. 26, 2024 (JP) 2024-026804

(51) Int. Cl. C23C 16/24; H01L 21/02

(52) U.S. Cl. CPC C23C 16/24; H01L 21/02211; H01L 21/02271

(57) ABSTRACT

A film-forming method includes forming a seed layer over a substrate; supplying a silicon-containing gas to the substrate and forming, over the seed layer, a bulk layer containing silicon; and thermally treating the substrate and crystallizing the bulk layer. The formation of the bulk layer includes supplying an impurity-containing gas during at least a part of a supply period of the silicon-containing gas.

### CROSS-REFERENCE TO RELATED APPLICATIONS

This application is based upon and claims priority to Japanese Patent Application No. 2024-026804,filed on Feb. 26, 2024, the entire contents of which are incorporated herein by reference.

### BACKGROUND

### 1. Field of the Invention

The present disclosure relates to a film-forming method and a film-forming apparatus.

### 2. Description of the Related Art

There is a known technique in which an amorphous silicon film doped with impurities that suppress the progress of crystallization and a non-doped amorphous silicon film are stacked over an insulating film in this order, and then the stacked amorphous silicon film is crystallized. See, for example, Japanese Patent Application Publication No. 2015-115435.

### SUMMARY

A film-forming method according to an aspect of the present disclosure includes: forming a seed layer over a substrate; supplying a silicon-containing gas to the substrate and forming, over the seed layer, a bulk layer containing silicon; and thermally treating the substrate and crystallizing the bulk layer. The formation of the bulk layer includes supplying an impurity-containing gas during at least a part of a supply period of the silicon-containing gas.

### BRIEF DESCRIPTION OF THE DRAWINGS

FIG. 1 is a flowchart illustrating a film-forming method according to an embodiment of the present disclosure; FIG. 2A is a cross-sectional view illustrating a process of the film-forming method according to the embodiment; FIG. 2B is a cross-sectional view illustrating the process of the film-forming method according to the embodiment;

FIG. 2C is a cross-sectional view illustrating the process of the film-forming method according to the embodiment;

FIG. 2D is a cross-sectional view illustrating the process of the film-forming method according to the embodiment;

FIG. 3A is a cross-sectional view illustrating a first example of a bulk layer forming step in the film-forming method of FIGS. 2A to 2D;

FIG. 3B is a cross-sectional view illustrating the first example of the bulk layer forming step in the film-forming method of FIGS. 2A to 2D;

FIG. 4A is a cross-sectional view illustrating a second example of the bulk layer forming step in the film-forming method of FIGS. 2A to 2D;

FIG. 4B is a cross-sectional view illustrating the second example of the bulk layer forming step in the film-forming method of FIGS. 2A to 2D;

FIG. 4C is a cross-sectional view illustrating the second example of the bulk layer forming step in the film-forming method of FIGS. 2A to 2D;

FIG. 5 is a vertical cross-sectional view illustrating a film-forming apparatus according to an embodiment of the present disclosure;

FIG. 6 is a horizontal cross-sectional view illustrating the film-forming apparatus according to the embodiment;

FIG. 7 is a table in which amorphous silicon films are compared in terms of carbon concentration;

FIG. 8 is a graph in which polycrystalline silicon films are compared in terms of extinction coefficient; and

FIG. 9 is a graph in which polycrystalline silicon films are compared in terms of weighted average crystal grain size.

### DETAILED DESCRIPTION OF THE DISCLOSURE

The present disclosure provides a technique capable of controlling crystallinity of a silicon film.

Hereinafter, non-limiting embodiments of the present disclosure will be described with reference to the drawings. In the drawings, the same or corresponding members or parts will be denoted by the same or corresponding reference numerals, and duplicate description thereof will be omitted.

### Film-Forming Method

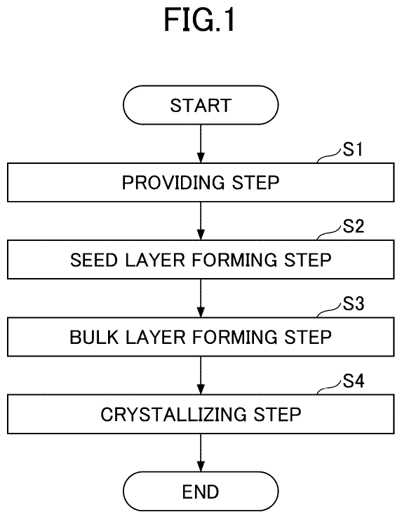

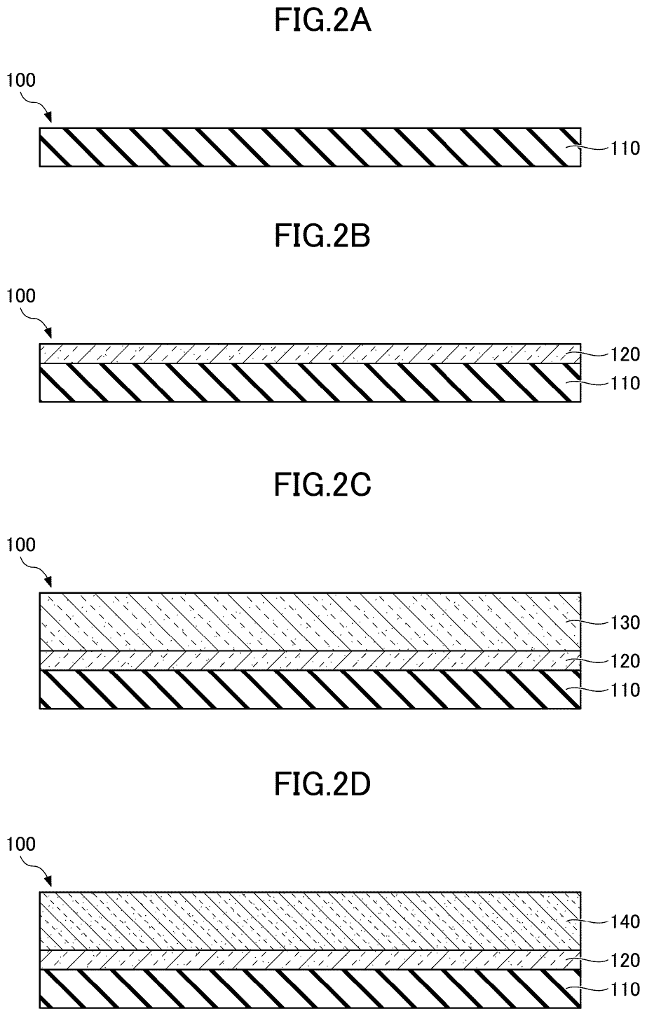

A film-forming method according to an embodiment of the present disclosure will be described with reference to FIGS. 1 to 4. FIG. 1 is a flowchart illustrating the film-forming method according to the embodiment. FIGS. 2A to 2D are cross-sectional views illustrating a process of the film-forming method according to the embodiment. As illustrated in FIG. 1, the film-forming method according to the embodiment includes a providing step S1, a seed layer forming step S2, a bulk layer forming step S3, and a crystallizing step S4.

As illustrated in FIG. 2A, the providing step S1 includes providing a substrate 100 having a surface over which an insulating film 110 is formed. The substrate 100 is, for example, a semiconductor substrate, such as a silicon substrate or the like. The insulating film 110 is, for example, a silicon oxide film. The insulating film 110 may be a silicon nitride film, a silicon oxynitride film, or the like.

The seed layer forming step S2 is performed after the providing step S1. As illustrated in FIG. 2B, the seed layer forming step S2 includes supplying a first silicon-containing gas to the substrate 100 and forming a seed layer 120 over the insulating film 110. The first silicon-containing gas is, for example, an aminosilane-based gas.

Examples of the aminosilane-based gas include a diisopropylaminosilane (DIPAS) gas, a trisdimethylaminosilane (3DMAS) gas, a bis (tert-butylamino) silane (BTBAS) gas, and the like. The first silicon-containing gas may be a high-order silane-based gas containing two or more silicon (Si) atoms in one molecule. Examples of the high-order silane-based gas include a disilane (Si₂H₆) gas, a trisilane (Si₃H₈) gas, a tetrasilane (Si₄H₁₀) gas, and the like. The seed layer 120 is not limited to a monolayer film, and may be a stacked film. The seed layer 120 may be a stacked film in which a first seed layer formed using an aminosilane-based gas and a second seed layer formed using a high-order silane-based gas are stacked in this order. The seed layer forming step S2 may include maintaining the substrate 100 at a first temperature. The first temperature is, for example, 300 degrees Celsius (° C.) or higher and 400 degrees Celsius (° C.) or lower.

The bulk layer forming step S3 is performed after the seed layer forming step S2. As illustrated in FIG. 2C, the bulk layer forming step S3 includes supplying a second silicon-containing gas to the substrate 100 and forming, on the seed layer 120, a bulk layer 130 containing silicon. The second silicon-containing gas is, for example, a monosilane (SiH₄) gas. The second silicon-containing gas may be a high-order silane-based gas, such as a disilane gas, a trisilane gas, a tetrasilane gas, or the like.

The bulk layer forming step S3 includes supplying an impurity-containing gas during at least a part of a supply period of the second silicon-containing gas. At least a part of the supply period of the second silicon-containing gas is, for example, a period that is 10% or more and 20% or less of the supply period of the second silicon-containing gas. The impurity-containing gas is, for example, an ethylene (C₂H₂) gas. The impurity-containing gas may be a carbon-containing gas other than an ethylene gas. The impurity contained in the impurity-containing gas may be at least one element selected from the group consisting of phosphorus (P), boron (B), fluorine (F), chlorine (Cl), oxygen (O), nitrogen (N), and hydrogen. The bulk layer forming step S3 may include maintaining the substrate 100 at a second temperature. The second temperature is higher than the first temperature. The second temperature is, for example, 400° C. or higher and 500° C. or lower.

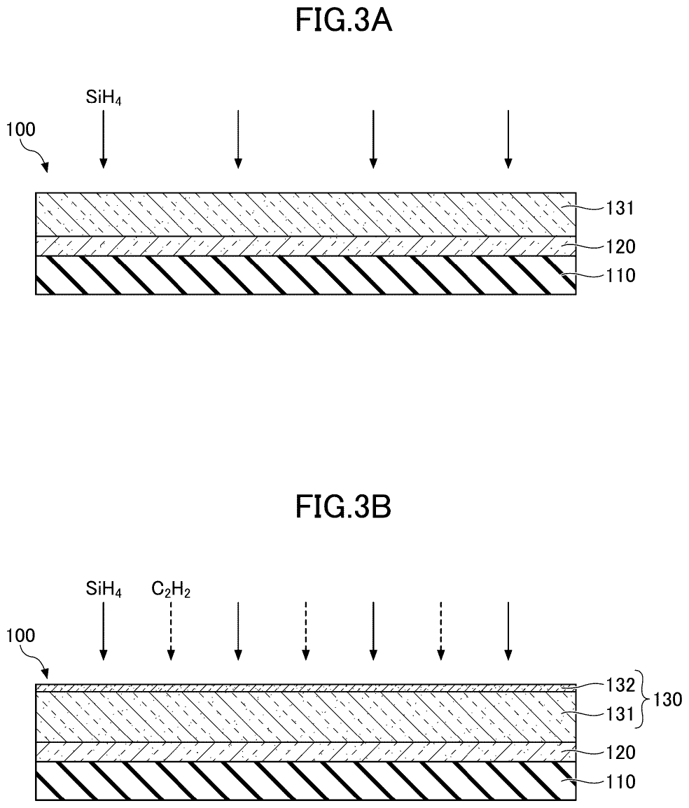

FIGS. 3A and 3B are cross-sectional views illustrating a first example of the bulk layer forming step S3 in the film-forming method of FIGS. 2A to 2D. In the first example of the bulk layer forming step S3, first, as illustrated in FIG. 3A, a monosilane gas is supplied to the substrate 100, and a first amorphous silicon film 131 is formed over the seed layer 120. After a first period of time has passed since supply of the monosilane gas is started, as illustrated in FIG. 3B, supply of an ethylene gas is started in a state in which the supply of the monosilane gas is continued, and a second amorphous silicon film 132 doped with carbon is formed over the first amorphous silicon film 131. This forms the bulk layer 130 in which the first amorphous silicon film 131 and the second amorphous silicon film 132 are stacked in this order. The first period of time is, for example, longer than a period that is half the overall period of the bulk layer forming step S3. Thus, in the example of FIGS. 3A and 3B, the supply of the ethylene gas is started at a first point in time partway through the supply period of the monosilane gas, and is stopped at the end of the supply period of the monosilane gas.

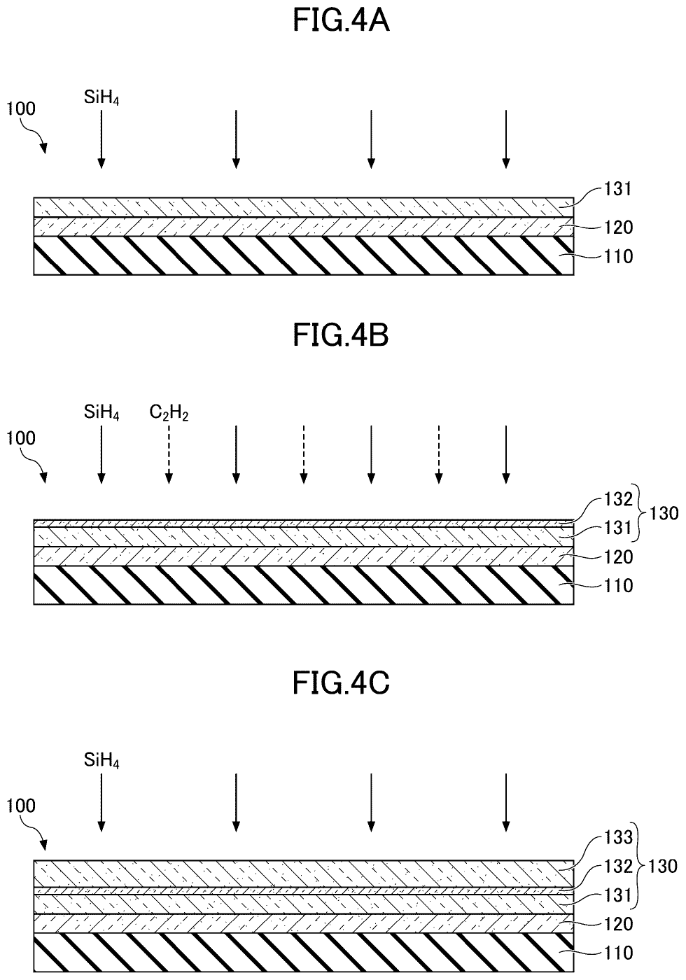

FIGS. 4A to 4C are cross-sectional views illustrating a second example of the bulk layer forming step S3 in the film-forming method of FIGS. 2A to 2D. In the second example of the bulk layer forming step S3, first, as illustrated in FIG. 4A, a monosilane gas is supplied to the substrate 100, and a first amorphous silicon film 131 is formed over the seed layer 120. After a second period of time has passed since supply of the monosilane gas is started, as illustrated in FIG. 4B, supply of an ethylene gas is started in a state in which the supply of the monosilane gas is continued, and a second amorphous silicon film 132 doped with carbon is formed over the first amorphous silicon film 131. After a third period of time has passed since the supply of the ethylene gas is started, as illustrated in FIG. 4C, the supply of the ethylene gas is stopped in a state in which the supply of the monosilane gas is continued, and a third amorphous silicon film 133 is formed over the second amorphous silicon film 132. This forms the bulk layer 130 in which the first amorphous silicon film 131, the second amorphous silicon film 132, and the third amorphous silicon film 133 are stacked in this order. A period of from a second point in time at which the supply of the ethylene gas is stopped until the end of the supply period of the monosilane gas is, for example, the same as a period of from the start of the supply period of the monosilane gas until the first point in time at which the supply of the ethylene gas is started. The period of from the second point in time at which the supply of the ethylene gas is stopped until the end of the supply period of the monosilane gas may be longer or shorter than the period of from the start of the supply period of the monosilane gas until the first point in time at which the supply of the ethylene gas is started. Thus, in the example of FIGS. 4A to 4C, the supply of the ethylene gas is started at the first point in time partway through the supply period of the monosilane gas, and is stopped at the second point in time partway through the supply period of the monosilane gas.

The crystallizing step S4 is performed after the bulk layer forming step S3. As illustrated in FIG. 2D, the crystallizing step S4 includes thermally treating the substrate 100 and crystallizing the bulk layer 130, thereby forming a polycrystalline silicon film 140. In the crystallizing step S4, for example, the substrate 100 is heated to a third temperature equal to or higher than the crystallization temperature of the bulk layer 130, and maintained at the third temperature. The third temperature is higher than the second temperature, e.g., 550° C. or higher and 900° C. or lower.

As described above, according to the film-forming method according to the embodiment, the seed layer forming step S2, the bulk layer forming step S3, and the crystallizing step S4 are performed in this order. The bulk layer forming step S3 includes supplying the impurity-containing gas during at least a part of the supply period of the second silicon-containing gas. In this case, crystallinity of the polycrystalline silicon film 140 can be controlled by changing the period and the timing of the supply of the impurity-containing gas. For example, when the polycrystalline silicon film 140 is used as a channel layer of a transistor, carrier mobility increases as the crystal grain size of the polycrystalline silicon film 140 increases. As a result, the performance of the transistor is increased.

### Film-Forming Apparatus

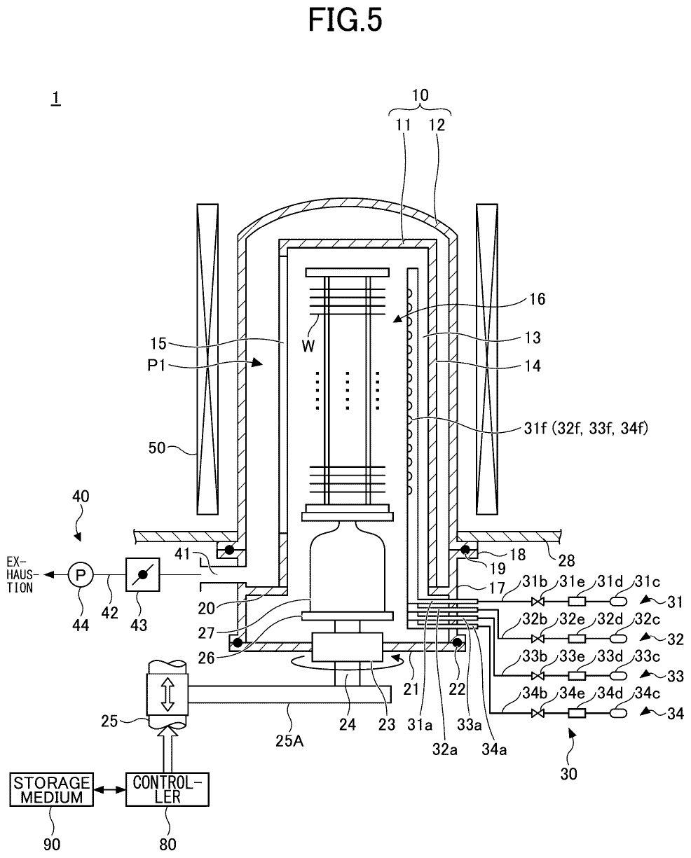

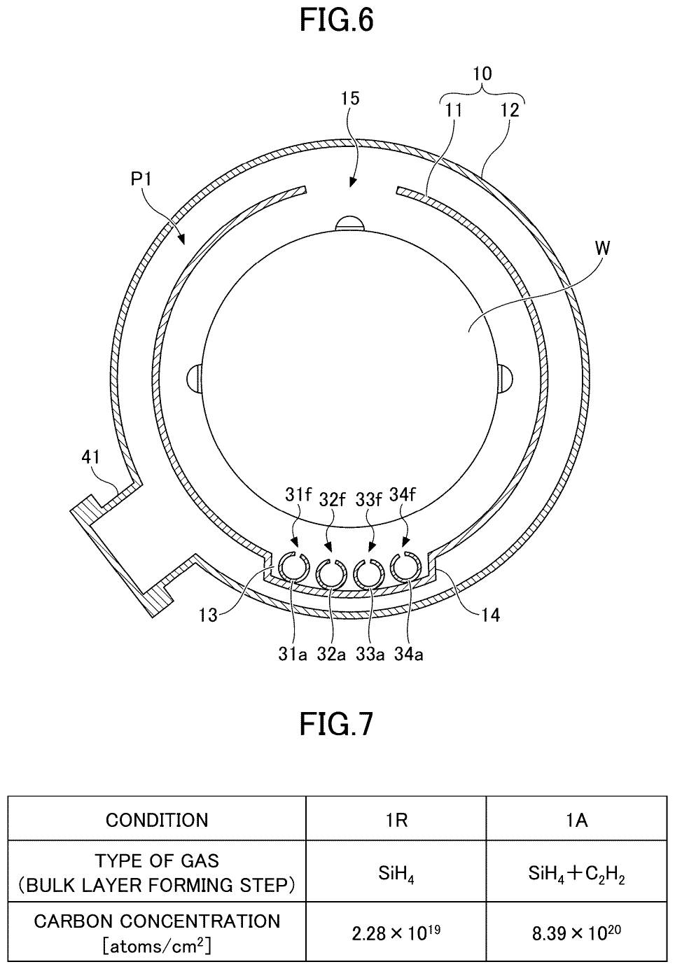

A film-forming apparatus 1 according to an embodiment of the present disclosure will be described with reference to FIGS. 5 and 6. FIG. 5 is a vertical cross-sectional view illustrating the film-forming apparatus 1 according to the embodiment. FIG. 6 is a horizontal cross-sectional view illustrating the film-forming apparatus 1 according to the embodiment.

The film-forming apparatus 1 is a batch-type apparatus configured to process a plurality of substrates W at one time. The substrates W are, for example, semiconductor wafers. The film-forming apparatus 1 includes a process chamber 10, a gas supply 30, a gas exhauster 40, a heater 50, and a controller 80.

The internal pressure of the process chamber 10 can be reduced. The process chamber 10 is configured to house the substrates W. The process chamber 10 includes an inner tube 11 and an outer tube 12. The inner tube 11 has a cylindrical shape having a ceiling and an opened bottom end. The outer tube 12 has a cylindrical shape having a ceiling, an opened bottom end, and covers the outside of the inner tube 11. The inner tube 11 and the outer tube 12 are formed of a heat-resistant material, such as quartz or the like. The inner tube 11 and the outer tube 12 have a double-tube structure in which they are arranged coaxially.

The side wall of the inner tube 11 is provided with a housing 13 configured to house a gas supply tube along the longitudinal direction (vertical direction) of the inner tube 11. For example, a part of the side wall of the inner tube 11 is projected outward to form a projecting portion 14, and the interior of the projecting portion 14 is formed as the housing 13.

The side wall of the inner tube 11 is provided with a rectangular opening 15 that is along the longitudinal direction of the inner tube 11. The opening 15 faces the housing 13.

The opening 15 is a gas exhaust opening that is formed to enable exhaustion of the gas in the inner tube 11. The length of the opening 15 is the same as the length of a boat 16, or is longer than the length of the boat 16, specifically, the opening 15 is formed to vertically extend beyond both vertical ends of the boat 16.

The bottom end of the process chamber 10 is supported by a cylindrical manifold 17. The manifold 17 is formed, for example, of stainless steel. A flange 18 is formed at the top end of the manifold 17. The flange 18 supports the bottom end of the outer tube 12. A sealing 19, such as an O-ring or the like, is provided between the flange 18 and the bottom end of the outer tube 12. Thus, the interior of the outer tube 12 is maintained to be airtight.

The inner wall of the upper portion of the manifold 17 is provided with an annular support 20. The support 20 supports the bottom end of the inner tube 11. A cover 21 is airtightly attached to an opening at the bottom end of the manifold 17 via a sealing 22, such as an O-ring or the like. Thus, the opening at the bottom end of the process chamber 10, i.e., the opening of the manifold 17, is airtightly closed. The cover 21 is formed, for example, of stainless steel.

The center portion of the cover 21 is provided, via a magnetic fluid seal 23, with a rotating shaft 24 that penetrates through the cover 21. The lower portion of the rotating shaft 24 is rotatably supported by an arm 25A of a raising and lowering mechanism 25 that is implemented by a boat elevator.

The top end of the rotating shaft 24 is provided with a rotating plate 26. A boat 16 configured to hold the substrates W is placed over the rotating plate 26 via a warming stage 27 formed of quartz. The boat 16 is rotated by rotating the rotating shaft 24. The boat 16 is vertically moved integrally with the cover 21 by raising and lowering the raising and lowering mechanism 25. Thus, the boat 16 is inserted into and removed from the process chamber 10. The boat 16 can be housed in the process chamber 10. The boat 16 holds the substrates W (e.g., 50 to 150 substrates) at intervals in a vertically stacked manner. The boat 16 substantially horizontally holds the substrates W at intervals in the vertical direction.

The gas supply 30 is configured to introduce various process gases into the inner tube 11. The gas supply 30 includes a DIPAS supply 31, a disilane supply 32, a monosilane supply 33, and an ethylene supply 34.

The DIPAS supply 31 includes a gas supply tube 31a in the process chamber 10, and a supply path 31b outside the process chamber 10. The supply path 31b includes a DIPAS source 31c, a mass flow controller 31d, and a valve 31e in order from upstream to downstream in the gas flow direction. Thus, the supply timing of the DIPAS gas in the DIPAS source 31c is controlled by the valve 31e, and the flow rate of the DIPAS gas is adjusted to a predetermined flow rate by the mass flow controller 31d. The DIPAS gas flows into the gas supply tube 31a from the supply path 31b, and is discharged into the process chamber 10 from the gas supply tube 31a. The DIPAS gas is an example of the first silicon-containing gas used in the seed layer forming step S2.

The disilane supply 32 includes a gas supply tube 32a in the process chamber 10, and a supply path 32b outside the process chamber 10. The supply path 32b includes a disilane source 32c, a mass flow controller 32d, and a valve 32e in order from upstream to downstream in the gas flow direction. Thus, the supply timing of the disilane gas in the disilane source 32c is controlled by the valve 32e, and the flow rate of the disilane gas is adjusted to a predetermined flow rate by the mass flow controller 32d. The disilane gas flows into the gas supply tube 32a from the supply path 32b, and is discharged into the process chamber 10 from the gas supply tube 32a. The disilane gas is an example of the first silicon-containing gas used in the seed layer forming step S2.

The monosilane supply 33 includes a gas supply tube 33a in the process chamber 10, and a supply path 33b outside the process chamber 10. The supply path 33b includes a monosilane source 33c, a mass flow controller 33d, and a valve 33e in order from upstream to downstream in the gas flow direction. Thus, the supply timing of the monosilane gas in the monosilane source 33c is controlled by the valve 33e, and the flow rate of the monosilane gas is adjusted to a predetermined flow rate by the mass flow controller 33d. The monosilane gas flows into the gas supply tube 33a from the supply path 33b, and is discharged into the process chamber 10 from the gas supply tube 33a. The monosilane gas is an example of the second silicon-containing gas used in the bulk layer forming step S3.

The ethylene supply 34 includes a gas supply tube 34a in the process chamber 10, and a supply path 34b outside the process chamber 10. The supply path 34b includes an ethylene source 34c, a mass flow controller 34d, and a valve 34e in order from upstream to downstream in the gas flow direction. Thus, the supply timing of the ethylene gas in the ethylene source 34c is controlled by the valve 34e, and the flow rate of the ethylene gas is adjusted to a predetermined flow rate by the mass flow controller 34d. The ethylene gas flows into the gas supply tube 34a from the supply path 34b, and is discharged into the process chamber 10 from the gas supply tube 34a. The ethylene gas is an example of the impurity-containing gas used in the bulk layer forming step S3.

The gas supply tubes 31a, 32a, 33a, and 34a are fixed to the manifold 17. The gas supply tubes 31a, 32a, 33a, and 34a are formed, for example, of quartz. The gas supply tubes 31a, 32a, 33a, and 34a vertically extend in a straight line near the inner tube 11, and bend in an L-shape in the manifold 17 and horizontally extend to penetrate through the manifold 17. The gas supply tubes 31a, 32a, 33a, and 34a are provided side by side along the circumferential direction of the inner tube 11 and are formed at the same height.

A plurality of discharge holes 31f, 32f, 33f, and 34f are provided at portions of the gas supply tubes 31a, 32a, 33a, and 34a that are positioned in the inner tube 11. The discharge holes 31f, 32f, 33f, and 34f are formed at predetermined intervals along the extending direction of the gas supply tubes 31a, 32a, 33a, and 34a. The discharge holes 31f, 32f, 33f, and 34f horizontally discharge gas toward the substrate W from the outside in the radial direction of the substrate W. The discharge holes 31f, 32f, 33f, and 34f discharge gas parallel to the main surface of the substrate W. The distance between the discharge holes is set, for example, to be equal to the distance between the substrates W held by the boat 16. The position of each discharge hole in the height direction is set, for example, at the middle position between the substrates W that are next to each other in the vertical direction. In this case, each discharge hole can efficiently supply gas to a facing surface between the substrates W next to each other.

The gas supply 30 may mix two or more types of gases together, and discharge the mixed gas from a single gas supply tube. The gas supply tubes 31a, 32a, 33a, and 34a may have different shapes and arrangements. The gas supply 30 may further include a gas supply tube configured to supply a different type of gas, e.g., an inert gas.

The gas exhauster 40 is configured to exhaust the gas that is discharged through the opening 15 from the interior of the inner tube 11 and then discharged from a gas outlet 41 through a space P1 between the inner tube 11 and the outer tube 12. The gas outlet 41 is formed at the side wall upward of the manifold 17 and above the support 20. A gas exhaust path 42 is connected to the gas outlet 41. A pressure regulating valve 43 and a vacuum pump 44 are sequentially disposed in the gas exhaust path 42 with a gap such that the internal gas of the process chamber 10 can be exhausted.

The heater 50 is provided around the outer tube 12. The heater 50 is provided, for example, on a base plate 28. The heater 50 has a cylindrical shape to cover the outer tube 12. The heater 50 includes, for example, a heating element, and is configured to heat the substrates W in the process chamber 10.

The controller 80 is configured to control the driving of each component of the film-forming apparatus 1. The controller 80 may be, for example, a computer. One or more programs for the computer configured to perform the driving of each component of the film-forming apparatus 1 are stored in a storage medium 90. The storage medium 90 may be, for example, a flexible disk, a compact disk, a hard disk, a flash memory, a DVD, or the like.

### Driving of Film-Forming Apparatus

How the film-forming apparatus 1 is driven when performing the film-forming method according to the embodiment will be described below.

First, the controller 80 controls the raising and lowering mechanism 25, carries the boat 16 holding the substrates W into the process chamber 10, and airtightly closes the opening at the bottom end of the process chamber 10 with the cover 21. Subsequently, the controller 80 controls the gas exhauster 40 to reduce the internal pressure of the process chamber 10, and controls the heater 50 to adjust the temperature of the substrate W to the first temperature. Each substrate W may be the substrate 100 described above.

Next, the seed layer forming step S2 is performed. In a state in which the temperature of the substrates W is maintained at the first temperature by controlling the heater 50, the controller 80 controls the gas supply 30 to supply a DIPAS gas into the process chamber 10, and also controls the gas exhauster 40 to maintain the internal pressure of the process chamber 10 at a predetermined pressure. Thus, a first seed layer is formed over the insulating film 110. The first seed layer functions as a part of the seed layer 120. When the first seed layer is formed, an inert gas, such as a nitrogen gas or the like, may be supplied into the process chamber 10 along with the DIPAS gas.

Subsequently, in a state in which the temperature of the substrates W is maintained at the first temperature by controlling the heater 50, the controller 80 controls the gas supply 30 to supply a disilane gas into the process chamber 10, and also controls the gas exhauster 40 to maintain the internal pressure of the process chamber 10 at a predetermined pressure. Thus, a second seed layer is formed over the first seed layer. The second seed layer functions as a part of the seed layer 120. When the second seed layer is formed, an inert gas, such as a nitrogen gas or the like, may be supplied into the process chamber 10 along with the disilane gas.

Next, the bulk layer forming step S3 is performed. The controller 80 controls the heater 50 to adjust the temperature of the substrates W from the first temperature to the second temperature. Subsequently, in a state in which the temperature of the substrates W is maintained at the second temperature by controlling the heater 50, the controller 80 controls the gas supply 30 to supply a monosilane gas into the process chamber 10, and also controls the gas exhauster 40 to maintain the internal pressure of the process chamber 10 at a predetermined pressure. At this time, an ethylene gas is supplied during at least a part of the supply period of the monosilane gas. Thus, the bulk layer 130 is formed over the seed layer 120. When the bulk layer 130 is formed, an inert gas, such as a nitrogen gas or the like, may be supplied into the process chamber 10 along with the monosilane gas and the ethylene gas.

Next, the crystallizing step S4 is performed. The controller 80 controls the gas supply 30 to supply an inert gas into the process chamber 10, and also controls the heater 50 to adjust the temperature of the substrates W from the second temperature to the third temperature and maintain the temperature of the substrates W at the third temperature. Thus, the substrate 100 is thermally treated, and the bulk layer 130 is crystallized to form the polycrystalline silicon film 140.

Next, the controller 80 increases the internal pressure of the process chamber 10 to the atmospheric pressure, and also lowers the internal temperature of the process chamber 10 to a temperature at which the boat 16 can be carried out. Then, the controller 80 controls the raising and lowering mechanism 25 to carry the boat 16 out of the process chamber 10.

In the manner as described above, the film-forming method according to the embodiment can be performed in the film-forming apparatus 1. Although the above example has been described using the case in which the seed layer forming step S2, the bulk layer forming step S3, and the crystallizing step S4 are performed in the film-forming apparatus 1, some of the steps may be performed in a different apparatus. For example, the seed layer forming step S2 and the bulk layer forming step S3 may be performed in the film-forming apparatus 1, and the crystallizing step S4 may be performed in an apparatus that is different from the film-forming apparatus 1.

### EXAMPLES

### Example 1

In Example 1, a silicon substrate including an oxide film over the surface of the silicon substrate was provided, the provided silicon substrate was housed in the process chamber 10 of the film-forming apparatus 1, and an amorphous silicon film was formed over the oxide film under Condition 1R or 1A described below. Next, the carbon (C) concentration of the amorphous silicon film was measured through secondary ion mass spectrometry (SIMS).

### <Condition 1R>

Under Condition 1R, after a seed layer was formed over the oxide film, a monosilane gas was supplied to the silicon substrate, thereby forming the amorphous silicon film over the seed layer.

### <Condition 1A>

Under Condition 1A, after a seed layer was formed over the oxide film, a monosilane gas and an ethylene gas were simultaneously supplied to the silicon substrate, thereby forming the amorphous silicon film over the seed layer. Condition 1A is the same as Condition 1R except that the monosilane gas and the ethylene gas were simultaneously supplied for the formation of the amorphous silicon film.

FIG. 7 is a table in which the amorphous silicon films are compared in terms of carbon concentration. As illustrated in FIG. 7, the carbon concentration of the amorphous silicon film was 2.28×10¹⁹ atoms/cm² under Condition 1R and was 8.39×10²⁰ atoms/cm² under Condition 1A. This result indicates that the amorphous silicon film is doped with a larger number of carbon atoms by simultaneously supplying the monosilane gas and the ethylene gas for the formation of the amorphous silicon film.

### Example 2

In Example 2, a silicon substrate including an oxide film over the surface of the silicon substrate was provided, the provided silicon substrate was housed in the process chamber 10 of the film-forming apparatus 1, a seed layer and an amorphous silicon film were formed over the oxide film in this order, and the amorphous silicon film was thermally treated to form a polycrystalline silicon film. In Example 2, an amorphous silicon film was formed under Condition 2R, 2A, or 2B. Next, the extinction coefficient (k value) of the polycrystalline silicon film was determined through spectroscopic ellipsometry. The extinction coefficient is close to 0.25 when the silicon film is amorphous, and approaches 0.05 as crystallinity of the silicon film increases. In Example 2, the extinction coefficient was measured at a plurality of points in time corresponding to different periods for thermally treating the amorphous silicon film.

### <Condition 2R>

Under Condition 2R, the amorphous silicon film was formed over the seed layer by supplying a monosilane gas to the silicon substrate. In this case, the amorphous silicon film is a non-doped layer.

### <Condition 2A>

Under Condition 2A, the amorphous silicon film was formed by supplying a monosilane gas to the silicon substrate, starting supply of an ethylene gas at the first point in time partway through the supply period of the monosilane gas, and stopping the supply of the ethylene gas at the end of the supply period of the monosilane gas. In this case, the amorphous silicon film includes a non-doped layer and a doped layer in this order.

### <Condition 2B>

Under Condition 2B, the amorphous silicon film was formed by supplying a monosilane gas to the silicon substrate, starting supply of an ethylene gas at the first point in time partway through the supply period of the monosilane gas, and stopping the supply of the ethylene gas at the second point in time partway through the supply period of the monosilane gas. In this case, the amorphous silicon film includes a non-doped layer, a doped layer, and a non-doped layer in this order. Under Condition 2B, the thickness of the lower non-doped layer was made the same as the thickness of the upper non-doped layer, and the thickness of the doped layer was made smaller than the thickness of the non-doped layer.

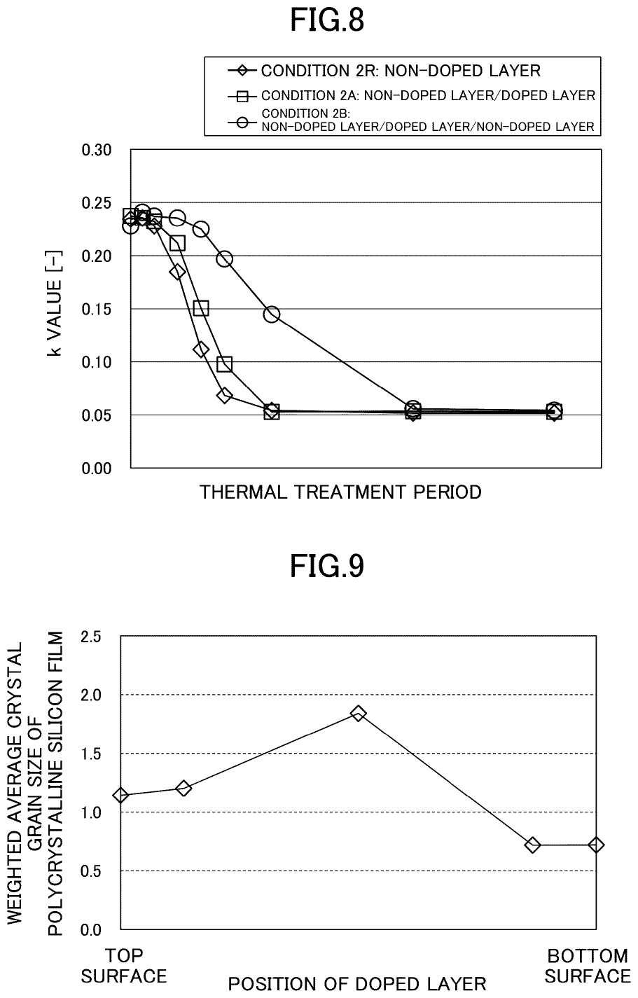

FIG. 8 is a graph in which the polycrystalline silicon films are compared in terms of extinction coefficient. In FIG. 8, the vertical axis indicates the extinction coefficient (k value) of the polycrystalline silicon films, and the horizontal axis indicates the thermal treatment period of the amorphous silicon films.

FIG. 8 indicates that the period for which the extinction coefficient approaches 0.05 from the start of the thermal treatment of the amorphous silicon film, i.e., the period required for crystallization of the amorphous silicon film, becomes longer in the order of Condition 2R, Condition 2A, and Condition 2B. This result indicates that the crystallization speed of the amorphous silicon film is reduced by introducing a doped layer into the amorphous silicon film. In particular, the crystallization speed of the amorphous silicon film is reduced when the doped layer is introduced at the middle position in the thickness direction of the amorphous silicon film (Condition 2B), compared to when the doped layer is introduced at the top of the amorphous silicon film (Condition 2A). When the crystallization speed of the amorphous silicon film is reduced, the crystal grain size of the polycrystalline silicon film is considered likely to increase.

### Example 3

In Example 3, a silicon substrate including an oxide film over the surface of the silicon substrate was provided, the provided silicon substrate was housed in the process chamber 10 of the film-forming apparatus 1, a seed layer and an amorphous silicon film were formed over the oxide film in this order, and the amorphous silicon film was thermally treated to form a polycrystalline silicon film. In Example 3, the amorphous silicon film was formed under Condition 3R, 3A, 3B, 3C, 3D, or 3E. The thickness of the amorphous silicon film was set to be the same under all of the conditions. Next, the weighted average crystal grain size of the polycrystalline silicon film was determined through electron backscatter diffraction (EBSD). The weighted average crystal grain size is an average crystal grain size calculated using the area weighted method.

### <Condition 3R>

Under Condition 3R, the amorphous silicon film was formed over the seed layer by supplying a monosilane gas to the silicon substrate. In this case, the amorphous silicon film is a non-doped layer.

### <Condition 3A>

Under Condition 3A, the amorphous silicon film was formed by supplying a monosilane gas to the silicon substrate, starting supply of an ethylene gas at the first point in time partway through the supply period of the monosilane gas, and stopping the supply of the ethylene gas at the end of the supply period of the monosilane gas. In this case, the amorphous silicon film includes a non-doped layer and a doped layer in this order.

### <Condition 3B>

Under Condition 3B, the amorphous silicon film was formed by supplying a monosilane gas to the silicon substrate, starting supply of an ethylene gas at the first point in time partway through the supply period of the monosilane gas, and stopping the supply of the ethylene gas at the second point in time partway through the supply period of the monosilane gas. In this case, the amorphous silicon film includes a non-doped layer, a doped layer, and a non-doped layer in this order. Under Condition 3B, the timings of the start and the stop of the supply of the ethylene gas were controlled such that the doped layer was positioned to be closer to the top surface from the middle position in the thickness direction of the amorphous silicon film. The thickness of the doped layer was the same as the thickness of the doped layer under Condition 3A.

### <Condition 3C>

Under Condition 3C, the timings of the start and the stop of the supply of the ethylene gas were controlled such that the doped layer was positioned at the middle position in the thickness direction of the amorphous silicon film. The other conditions are the same as those in Condition 3B.

### <Condition 3D>

Under Condition 3D, the timings of the start and the stop of the supply of the ethylene gas were controlled such that the doped layer was positioned to be closer to the bottom surface rather than at the middle position in the thickness direction of the amorphous silicon film. The other conditions are the same as those in Condition 3B.

### <Condition 3E>

Under Condition 3E, the amorphous silicon film was formed by supplying a monosilane gas to the silicon substrate, starting supply of an ethylene gas from the start of the supply period of the monosilane gas, and stopping the supply of the ethylene gas at the second point in time partway through the supply period of the monosilane gas. In this case, the amorphous silicon film includes a doped layer and a non-doped layer in this order. The thickness of the doped layer is the same as the thickness of the doped layer in Condition 3A.

FIG. 9 is a graph in which the polycrystalline silicon films are compared in terms of weighted average crystal grain size. In FIG. 9, the vertical axis indicates the weighted average crystal grain size of the polycrystalline silicon film. Specifically, the weighted average crystal grain sizes of the polycrystalline silicon films in Conditions 3A to 3E are indicated as relative values, with the weighted average crystal grain size of the polycrystalline silicon film in Condition 3A being set as “1”. In FIG. 9, the horizontal axis indicates the position of the doped layer.

As illustrated in FIG. 9, the weighted average crystal grain size is changed by changing the position of the doped layer in the thickness direction of the polycrystalline silicon film. This result indicates that crystallinity of the polycrystalline silicon film can be controlled by changing the position of the doped layer in the thickness direction of the polycrystalline silicon film.

As illustrated in FIG. 9, compared to the polycrystalline silicon film without the doped layer, the weighted average crystal grain size becomes larger when the doped layer is introduced in a range from the top surface to the middle position of the polycrystalline silicon film in the thickness direction of the polycrystalline silicon film. In particular, when the doped layer is introduced at the middle position in the thickness direction of the polycrystalline silicon film, the weighted average crystal grain size 1.8 times larger than that of the polycrystalline silicon film without the doped layer is obtained.

As illustrated in FIG. 9, compared to the polycrystalline silicon film without the doped layer, the weighted average crystal grain size becomes smaller when the doped layer is introduced to be closer to the bottom surface rather than at the middle position of the polycrystalline silicon film in the thickness direction of the polycrystalline silicon film.

The embodiments disclosed herein should be considered to be exemplary in all respects, not to be restrictive. Omissions, substitutions, and modifications may be made in various forms to the above-described embodiments without departing from the scope and intent of the claims recited.

Although the above embodiments have been described using the case in which the process chamber has a double-tube structure, the present disclosure is not limited to this. For example, the process chamber may have a single-tube structure.

Although the above embodiments have been described using the case in which the film-forming apparatus is an apparatus configured to supply gas from a gas supply tube disposed along the longitudinal direction of the process chamber and exhaust the gas from a slit disposed to face the gas supply tube, the present disclosure is not limited to this. For example, the film-forming apparatus may be an apparatus configured to supply gas from a gas supply tube disposed along the longitudinal direction of the boat and exhaust the gas from a gas exhaust opening disposed above the boat. For example, the film-forming apparatus may be an apparatus configured to supply a process gas from a gas supply tube disposed below the process chamber and exhaust the gas from a gas exhaust opening disposed above the process chamber.

Although the above embodiments have been described using the case in which the film-forming apparatus is a batch-type apparatus configured to process a plurality of substrates at one time, the present disclosure is not limited to this. For example, the film-forming apparatus may be a single-wafer type apparatus configured to process substrates one by one. For example, the film-forming apparatus may be a semi-batch-type apparatus configured to process a plurality of substrates disposed on a rotation table by rotating the rotation table to allow each of the substrates to revolve and repeatedly pass through process gas supply regions disposed along a radius direction of the rotation table.

According to the present disclosure, crystallinity of a silicon film can be controlled.

What is claimed is:

1. A film-forming method, comprising:
forming a seed layer over a substrate;
supplying a silicon-containing gas to the substrate and forming, over the seed layer, a bulk layer containing silicon; and
thermally treating the substrate and crystallizing the bulk layer, wherein
the formation of the bulk layer includes supplying an impurity-containing gas during at least a part of a supply period of the silicon-containing gas.

2. The film-forming method according to claim 1, wherein
the supply of the impurity-containing gas is started at a first point in time partway through the supply period of the silicon-containing gas.

3. The film-forming method according to claim 1, wherein
the supply of the impurity-containing gas is stopped at a second point in time partway through the supply period of the silicon-containing gas.

4. The film-forming method according to claim 2, wherein
the supply of the impurity-containing gas is stopped at a second point in time partway through the supply period of the silicon-containing gas.

5. The film-forming method according to claim 3, wherein
a period of from the second point in time until an end of the supply period of the silicon-containing gas is same as a period of from a start of the supply period of the silicon-containing gas until a point in time at which the supply of the impurity-containing gas is started.

6. The film-forming method according to claim 4, wherein
a period of from the second point in time until an end of the supply period of the silicon-containing gas is same as a period of from a start of the supply period of the silicon-containing gas until the first point in time.

7. The film-forming method according to claim 1, wherein
the supply of the impurity-containing gas is stopped at an end of the supply period of the silicon-containing gas.

8. The film-forming method according to claim 2, wherein
the supply of the impurity-containing gas is stopped at an end of the supply period of the silicon-containing gas.

9. The film-forming method according to claim 1, wherein
the substrate includes an insulating film over a surface of the substrate, and
the seed layer is formed over the insulating film.

10. The film-forming method according to claim 1, wherein
the silicon-containing gas is a monosilane gas, and
the impurity-containing gas is an ethylene gas.

11. A film-forming apparatus, comprising:
a process chamber configured to house a substrate;
a supply configured to supply a silicon-containing gas and an impurity-containing gas into the process chamber;
a gas exhauster configured to exhaust gas in the process chamber;
a heater configured to heat the substrate; and
a controller configured to control the supply, the gas exhauster, and the heater, the controller including a memory and a processor connected to the memory, and the processor being configured to
form a seed layer over the substrate,
supply the silicon-containing gas to the substrate and form, over the seed layer, a bulk layer containing silicon,
thermally treat the substrate and crystallize the bulk layer, and
supply, in the formation of the bulk layer, the impurity-containing gas during at least a part of a supply period of the silicon-containing gas.
